(19) United States
(12) Patent Application Publication
(10) Pub. No.: US 2025/0008728 A1
(43) Pub. Date: Jan. 2, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Yun Cheol HAN, Gyeonggi-do (KR)

(21) Appl. No.: 18/474,219

(22) Filed: Sep. 26, 2023

(30) Foreign Application Priority Data
Jun. 27, 2023 (KR) 10-2023-0082735

(51) Int. Cl. H10B 43/10; H10B 41/10; H10B 41/27; H10B 43/27

(52) U.S. Cl. CPC H10B 43/10; H10B 41/10; H10B 41/27; H10B 43/27

(57) ABSTRACT

A semiconductor device may include a gate structure including insulating layers and conductive layers that are alternately stacked, a real channel structure extending through the gate structure, a slit structure extending in a first direction along the sidewall of the gate structure, a contact structure extending through the gate structure and that is electrically connected to at least one conductive layer, among the conductive layers, and a pair of first supports extending in an arc form along the sidewall of the contact structure and that includes concave and convex parts on sidewalls of the first supports.

### CROSS-REFERENCE TO RELATED APPLICATION

This application claims priority under 35 U.S.C. § 119 to Korean Patent Application No. 10-2023-0082735 filed on Jun. 27, 2023, which is incorporated herein by reference in its entirety.

### BACKGROUND

### 1. Technical Field

Various embodiments of the present invention relate generally to an electronic device and a method of manufacturing an electronic device and, more particularly, to a semiconductor device and a method of manufacturing a semiconductor device.

### 2. Related Art

The degree of integration of semiconductor devices is basically determined by the area that is occupied by a unit memory cell. As the improvement of the degree of integration of semiconductor devices in which a memory cell is formed on a substrate as a single layer recently reaches its limit, a three-dimensional semiconductor device in which memory cells are stacked in a three-dimensional arrangement over a substrate has been proposed. Furthermore, in order to improve operation characteristics and reliability of such 3-D semiconductor device, various structures, materials, and manufacturing methods are being developed.

### SUMMARY

The present invention relates generally to an improved 3-D semiconductor device (hereinafter simply referred to as a semiconductor device) and a method of manufacturing the semiconductor device.

In an embodiment of the present disclosure, a semiconductor device may include a gate structure including insulating layers and conductive layers that are alternately stacked, a real channel structure extending through the gate structure, a slit structure extending in a first direction along the sidewall of the gate structure, a contact structure extending through the gate structure and that is electrically connected to at least one conductive layer, among the conductive layers, and a pair of first supports extending in an arc form along the sidewall of the contact structure and that includes concave and convex parts on sidewalls of the first supports.

In an embodiment, a method for manufacturing a semiconductor device may include forming a stack by alternately stacking first material layers and second material layers, forming first openings extending through the stack and that are spaced apart from each other and arranged in an arc form, forming second openings extending in the arc form by connecting the first openings, forming, within the second openings, a pair of first supports extending in the arc form and that has concave and convex parts on sidewalls of the pair of first supports, and forming a contact structure that is disposed between the pair of first supports and that is connected to at least one second material layer, among the second material layers.

These and other features and advantages of the present invention will become apparent to those skilled in the art of the invention from the following detailed description in conjunction with the following drawings.

### BRIEF DESCRIPTION OF THE DRAWINGS

FIGS. 1A and 1B are diagrams for describing a semiconductor device according to an embodiment of the present disclosure.

FIGS. 2A, 2B, 3A, 3B, 4A, 4B, 5A, 5B, 6A, 6B, 7A, 7B, 8A, 8B, 9A, 9B, 10A, 10B, 11A, and 11B are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide an improved semiconductor device and a method of manufacturing the semiconductor device.

The semiconductor device may have a stable, resilient structure, improved reliability, and improved performance characteristics is provided.

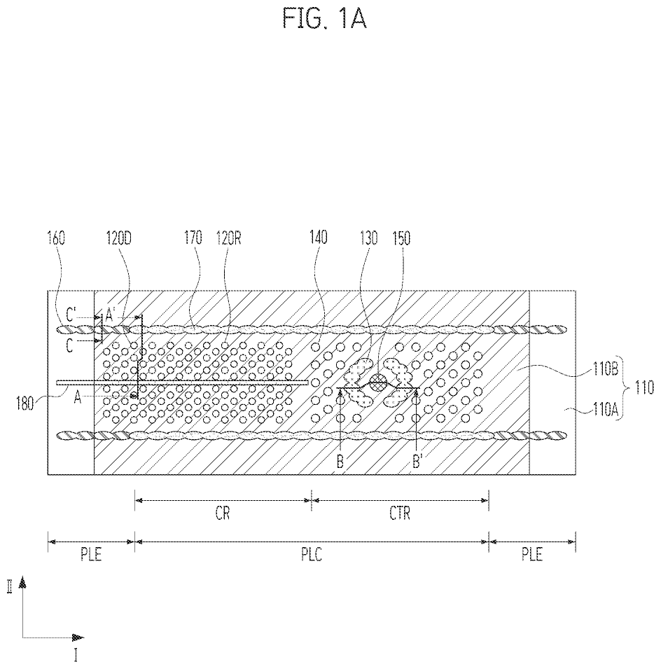

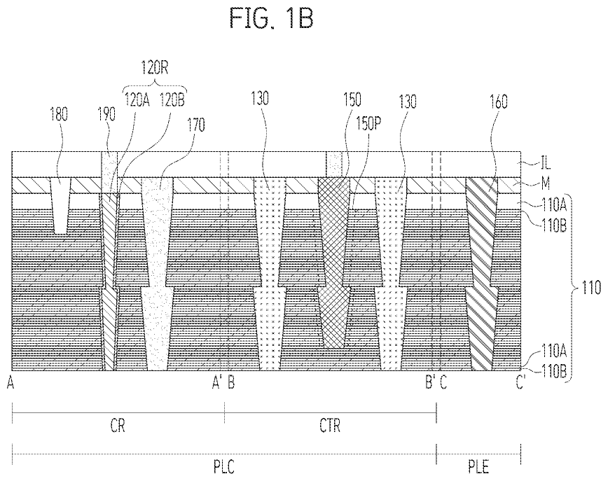

FIGS. 1A and 1B are diagrams for describing a semiconductor device according to an embodiment of the present disclosure. FIG. 1A is a plan view of the semiconductor device, and FIG. 1B is a cross-sectional view of FIG. 1A.

Referring to FIGS. 1A and 1B, the semiconductor device may include a gate structure 110, a real channel structure 120R, a dummy channel structure 120D, a first support 130, a second support 140, a contact structure 150, a separation structure 160, and a slit structure 170. The semiconductor device may further include an insulating structure 180, a contact via 190, a mask pattern M, and an interlayer insulating layer IL.

The gate structure 110 may include insulating layers 110A and conductive layers 110B that are alternately stacked. The gate structure 110 may include a cell region CR and a contact region CTR. Cell arrays including the real channel structure 120R, may be disposed in the cell region CR. The contact structure 150 connected to the cell arrays, may be disposed in the contact region CTR. The semiconductor device may include a plurality of plane regions. A plurality of memory blocks may be disposed within each plane region. The memory blocks may each include the gate structure 110. The cell region CR and contact region CTR of the gate structure 110 may be included in a plane center region PLC. A plane edge region PLE may be disposed at both ends of the plane center region PLC. For reference, the gate structure 110 of the plane edge region PLE may include a stack in which sacrificial layers (not illustrated) remain without being replaced with the conductive layers 110B in a process of forming the gate structure. That is, the gate structure 110 and the stack may coexist in the plane edge region PLE. The conductive layers 110B may each be a word line, a bit line, or a selection line. The insulating layers 110A may each include an insulating material, such as, for example, an oxide. The conductive layers 110B may each include a conductive material, such as, for example, tungsten or polysilicon.

The slit structure 170 may extend through the gate structure 110. The slit structure 170 may be disposed in the cell region CR and the contact region CTR of the gate structure 110 as shown in FIG. 1A. The slit structure 170 may generally have an elongated, line form and may extend in a first direction I along a sidewall of the gate structure 110. For example, the slit structure 170 may have a line form extending along the cell region CR and the contact region CTR. However, the slit structure 170 may not be straight lines but may include a plurality of concave and convex parts, respectively, as shown in FIG. 1A. The slit structure 170 may include an insulating material, such as, for example, an oxide. Also, the slit structure 170 may include a conductive material or a semiconductor material.

The separation structure 160 may extend through the gate structure 110. The separation structure 160 may be disposed in the plane edge region PLE of the gate structure 110. The separation structure 160 may be for preventing the plurality of gate structures 110 from being mutually electrically connected through the plane edge region PLE, when the plurality of gate structures 110 is formed by substituting sacrificial layers with the conductive layers 110B through a slit for forming the slit structure 170 in a process of manufacturing the semiconductor device. The separation structure 160 may have concave and convex parts on the sidewall of the separation structure 160. For example, the separation structure 160 may have a line form in which the separation structure 160 extends in the first direction I, and may include the concave and convex parts on the sidewall of the separation structure 160. The separation structure 160 may include an insulating material, such as, for example, an oxide.

The separation structure 160 and the slit structure 170 may extend in the first direction I along the sidewall of the gate structure 110 and may be mutually connected. For example, the slit structure 170 may protrude into the separation structure 160. The separation structure 160 and the slit structure 170 may be one layer or may be separate layers that are formed by separate processes. Accordingly, an interface may be present or might not be present between the separation structure 160 and the slit structure 170.

The real channel structures 120R may extend through the gate structure 110. The real channel structures 120R may be disposed in the cell region CR of the gate structure 110. The real channel structures 120R may be disposed between a pair of slit structures 170 that is adjacent to each other in a second direction II. The second direction II may intersect the first direction I, for example at 90 degrees as shown in FIG. 1A. The real channel structures 120R may be arranged in the first direction I, for example, in a zig-zag pattern and, also in the second direction II, also in a zig-zag pattern, inside the cell region CR. Alternatively, the real channel structures 120R may be arranged in a staggered form in which the centers of the real channel structures 120R have been dislocated. For example, the first direction I and the second direction II may be orthogonal to each other. The real channel structure 120R may include a channel layer 120A. The real channel structure 120R may further include a memory layer 120B that surrounds the channel layer 120A and an insulating core (not illustrated) within the channel layer 120A.

The dummy channel structures 120D may extend through the gate structure 110. The dummy channel structures 120D may be disposed between the pair of separation structures 160 that are adjacent to each other in the second direction II. The dummy channel structures 120D may be arranged in the first direction I and the second direction II. The dummy channel structures 120D may have a structure similar to the structure of the real channel structures 120R. For example, the dummy channel structure 120D may include a dummy channel layer, a dummy memory layer, and a dummy insulating core.

The insulating structure 180 may extend through the gate structure 110. For example, the insulating structure 180 may extend into the gate structure 110 through the mask pattern M. For example, the mask pattern M may be a mask pattern that remains without being removed in a process of manufacturing the semiconductor device. The insulating structure 180 may have a line form and may extend along the first direction I. The insulating structure 180 may be disposed between adjacent dummy channel structures 120D in the first direction. The insulating structure 180 may be disposed centrally between the real channel structures 120R. For example, the insulating structure 180 may penetrate part of at least one of the dummy channel structures 120D. In a variation of the described embodiment, the insulating structure 180 may penetrate part of at least one of the real channel structures 120R. The insulating structure 180 may have a lower height than the separation structure 160 or the slit structure 170. The insulating structure 180 may be disposed within the gate structure 110 and may have a height that penetrates a source selection line or a drain selection line. The insulating structure 180 may include an insulating material, such as, for example, an oxide.

The contact via 190 may be disposed on the gate structure 110 and may pass through the mask pattern M and the interlayer insulating layer IL which are stacked sequentially on the gate structure 110. For example, the interlayer insulating layer IL may be disposed on the mask pattern M. The interlayer insulating layer IL may include an insulating material, such as, for example, an oxide or nitride. The contact via 190 may be electrically connected to the real channel structure 120R and may be electrically connected to the contact structure 150. For example, the contact vias 190 may extend through the mask pattern M and the interlayer insulating layer IL and may be connected to the real channel structures 120R. The contact via 190 and may extend through the interlayer insulating layer IL and may be connected to the contact structure 150. The contact via 190 may be for mutually connecting structures disposed within the gate structure 110 and structures disposed on the gate structure 110. The contact via 190 may include a conductive material, such as, for example, tungsten.

The contact structure 150 may extend through the gate structure 110. The contact structure 150 may be disposed in the contact region CTR of the gate structure 110. The contact structure 150 may extend through the gate structure 110 and may be electrically connected to at least one conductive layer 110B, among the conductive layers 110B. The contact structure 150 may include insulating spacers 150P on the sidewall of the contact structure 150. The insulating spacers 150P may be electrically connected to the contact structure 150 and may be disposed at a level corresponding to the remaining conductive layers 110B. The insulating spacers 150P prevent the remaining conductive layers 110B, except the conductive layer 110B that is electrically connected to the contact structure 150, from being electrically connected to the contact structure 150. The contact structure 150 may include a conductive material, such as, for example, tungsten. The insulating spacers 150P may each include an insulating material, such as, for example, an oxide.

The first support 130 may extend through the gate structure 110. The first support 130 may be disposed in the contact region CTR of the gate structure 110. The first support 130 may extend in an arc form along the sidewall of the contact structure 150. The first support 130 may include concave and convex parts on the sidewall of the first support 130. For example, the first support 130 may be constructed in the arc form in which a plurality of pillars is mutually connected. As curved sidewalls of the pillars are connected, the sidewall of the first support 130 may include the concave and convex parts. A pair of first supports 130 may be spaced apart from each other in the first direction I. The contact structure 150 may be disposed between the pair of first supports 130. For example, the pair of first support 130 may have a symmetrical form.

If the first support 130 has a form in which the first support 130 extends in the arc form, the first support 130 can support the gate structure 110 more robustly than the first support 130 having a pillar form. The higher the height of the gate structure 110 is, the higher the height of the contact structure 150 needs to be. Furthermore, in view of process characteristics, the higher the height of the contact structure 150 is, the greater the width of the contact structure 150 needs to be. In such a case, an interval between the pair of first supports 130 may also need to be increased by considering that the width of the contact structure 150 is increased. For example, if the interval between the pair of first supports 130 is increased, a support force to support the gate structure 110 may be reduced. If the first supports 130 each have a pillar form, the support force of the first supports 130 to support the gate structure 110 may be limited. Accordingly, according to an embodiment of the present disclosure, the first supports 130 having a form in which the first supports 130 extend in the arc form by considering an increase in the width of the contact structure 150 may be formed. The pair of first supports 130 may extend in the arc form in which the pair of first supports 130 surrounds a region in which the contact structure 150 will be formed. Accordingly, the bending of the gate structure 110 in the region in which the contact structure 150 will be formed can be reduced.

In a process of manufacturing the semiconductor device, the first supports 130 and the separation structure 160 may be simultaneously formed. Accordingly, the first support 130 may have substantially the same height as the separation structure 160 or may include substantially the same material as the separation structure 160. For example, the first support 130 may have substantially the same height as the separation structure 160. Furthermore, the first support 130 may include substantially the same material as the separation structure 160. For example, the first support 130 may include oxide. However, the present disclosure is not limited to such an example, and the first support 130 and the separation structure 160 might not be simultaneously formed. For example, the first support 130 and the separation structure 160 may have different heights and may include different materials.

For reference, although not illustrated in FIGS. 1A and 1B, the semiconductor device may include several pairs of first supports 130 and include a plurality of contact structures 150. The plurality of contact structures 150 may each be disposed between the pair of first supports 130. The plurality of contact structures 150 may be electrically connected to the conductive layers 110B of the gate structure 110, respectively. Accordingly, the heights of the plurality of contact structures 150 may be different from each other.

The second support 140 may extend through the gate structure 110. The second support 140 may be disposed in the contact region CTR of the gate structure 110. The second supports 140 may be disposed by being spaced apart from the first supports 130. The second supports 140 may be for reducing the bending of the gate structure 110 like the first supports 130. The second supports 140 may be arranged in the first direction I and the second direction II. The second supports 140 may be arranged in a staggered form in which the centers of the second supports 140 have been dislocated. The second supports 140 may be regularly arranged unlike the first supports 130. The second support 140 may have a pillar form. The second support 140 may include an insulating material, such as, for example, an oxide.

According to the aforementioned structure, the first support 130 may extend in the arc form, and can support the gate structure 110 more robustly than the first support 130 having a pillar form. Accordingly, the first support 130 can prevent the gate structure 110 from being bent in a process of manufacturing the semiconductor device. That is, the height of the gate structure 110 may be increased, and the height of the contact structure 150 to be connected to the conductive layer 110B disposed under the gate structure 110 may also be increased.

Furthermore, in a process of manufacturing the semiconductor device, the first support 130 and the separation structure 160 may be simultaneously formed. The first support 130 and the separation structure 160 may have substantially the same height. The first support 130 and the separation structure 160 may include substantially the same material. Namely, a process of forming the semiconductor device can be simplified by simplifying a process of forming the first support 130 and a process of forming the separation structure 160.

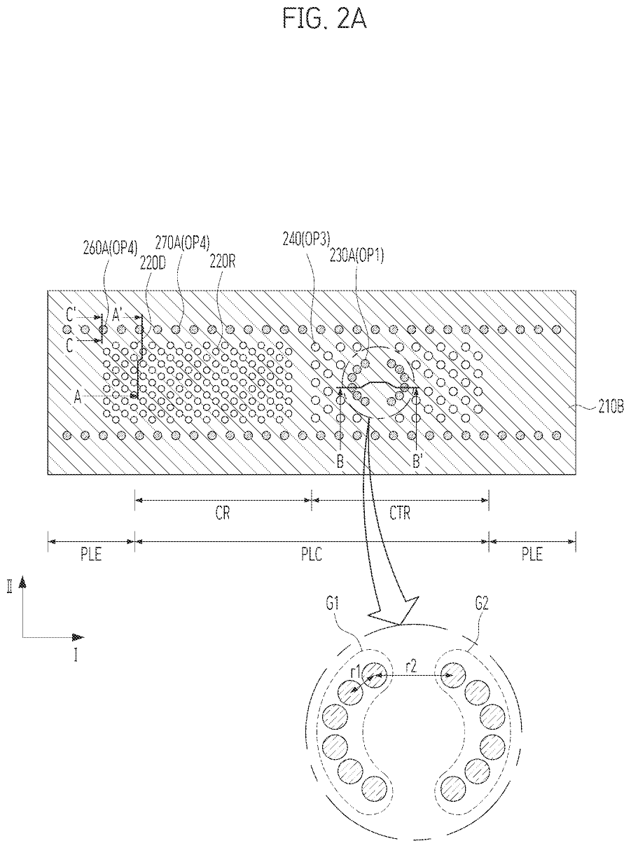

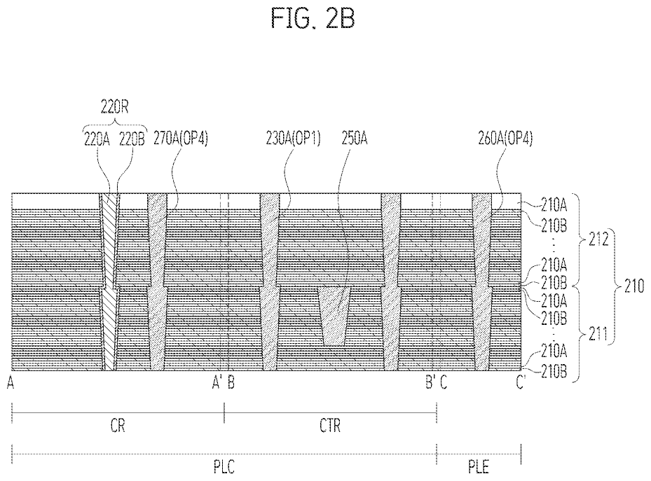

FIGS. 2A, 2B, 3A, 3B, 4A, 4B, 5A, 5B, 6A, 6B, 7A, 7B, 8A, 8B, 9A, 9B, 10A, 10B, 11A, and 11B are diagrams for describing a method of manufacturing a semiconductor device according to an embodiment of the present disclosure. Each of FIGS. 2A, 3A, 4A, 5A, 6A, 7A, 8A, 9A, 10A, and 11A is a plan view of the semiconductor device. Each of FIGS. 2B, 3B, 4B, 5B, 6B, 7B, 8B, 9B, 10B, and 11B is a cross-sectional view of each of FIGS. 2A, 3A, 4A, 5A, 6A, 7A, 8A, 9A, 10A, and 11A. Hereinafter, a description of contents redundant with the aforementioned contents may be omitted.

Referring to FIGS. 2A and 2B, a first sub-stack 211 may be formed by alternately stacking first material layers 210A and second material layers 210B. First sacrificial contact structures 250A may be formed within the first sub-stack 211. The first sacrificial contact structure 250A may penetrate part of the first sub-stack 211. The first sacrificial contact structure 250A may include a sacrificial material, such as, for example, polysilicon or carbon. For reference, although not illustrated in this drawing, the first sacrificial contact structure 250A may be formed in a plural number. The first sacrificial contact structures 250A may have different heights so that the first sacrificial contact structures 250A are connected to at least one of the first material layers 210A of the first sub-stack 211, respectively.

Next, a second sub-stack 212 may be formed by alternately stacking the first material layers 210A and the second material layers 210B on the first sub-stack 211. Accordingly, a stack 210 including the first sub-stack 211 and the second sub-stack 212 may be defined. Accordingly, the stack 210 may include the first material layers 210A and the second material layers 210B that are alternately stacked. The stack 210 may include a cell region CR and a contact region CTR. The cell region CR and contact region CTR of the stack 210 may be included in a plane center region PLC. A plane edge region PLE may be disposed at both ends of the plane center region PLC.

First openings OP1 extending through the stack 210 may be formed. The first openings OP1 may be formed in the contact region CTR. The first openings OP1 may extend through the stack 210 and may be formed so that the first openings OP1 are arranged in an arc form by being spaced apart from each other. For example, the first openings OP1 may be arranged in the arc form by considering a region in which a contact structure (not illustrated) will be formed. The first openings OP1 may be divided into a first group G1 including first openings OP1 that are arranged at first intervals r1 and a second group G2 that has been spaced apart from the first group G1 at a second interval r2. When the first group G1 is formed, the second group G2 may be formed. The first interval r1 may mean an interval between the first openings OP1 that constitute the first group G1 and the second group G2. The second interval r2 may mean the interval r2 between the first group G1 and the second group G2. The second interval r2 may be greater than the first interval r1. By forming the second interval r2 to be greater than the first interval r1, the first group G1 and the second group G2 can be prevented from being connected in a subsequent process. The first group G1 and the second group G2 may be spaced apart from each other in a first direction I. The first group G1 and the second group G2 may have a symmetrical form. Next, first sacrificial supports 230A may be formed within the first openings OP1, respectively. The first sacrificial supports 230A may each include a sacrificial material, such as, for example, carbon or polysilicon.

Third openings OP3 extending through the stack 210 may be formed. The third openings OP3 may be formed in the contact region CTR. The third openings OP3 may extend through the stack 210, and may be arranged in the first direction I and a second direction II that intersects the first direction I. For example, the second direction II may be orthogonal to the first direction I. Furthermore, the third openings OP3 may be arranged in a staggered form in which the centers of the third openings OP3 have been dislocated. The third openings OP3 may be regularly arranged unlike the first openings OP1. Next, second supports 240 each having a pillar form may be formed within the third openings OP3, respectively. The second supports 240 may each include an insulating material, such as, for example, an oxide.

Fourth openings OP4 extending through the stack 210 may be formed. The fourth openings OP4 extending through the stack 210 and that are arranged by being spaced apart from each other in the first direction I may be formed. When the first openings OP1 are formed, the fourth openings OP4 may be formed. The fourth openings OP4 may be formed in a plane center region PLC and the plane edge regions PLE. Next, sacrificial separation structures 260A may be formed within the fourth openings OP4 formed in the plane edge regions PLE, respectively. Sacrificial slit structures 270A may be formed within the fourth openings OP4 formed in the plane center region PLC, respectively. The sacrificial separation structures 260A and the sacrificial slit structures 270A may be simultaneously formed. The sacrificial separation structures 260A and the sacrificial slit structures 270A may each include a sacrificial material, such as, for example, carbon or polysilicon.

Real channel structures 220R extending through the stack 210 may be formed. The real channel structures 220R may be formed in the cell region CR. The real channel structures 220R may be formed between the fourth openings OP4 of the plane center region PLC. When the real channel structures 220R are formed, the dummy channel structures 220D may be formed. Dummy channel structures 220D may be formed between the fourth openings OP4 of the plane edge region PLE. The real channel structures 220R may each include a channel layer 220A and a memory layer 220B that surrounds the channel layer 220A. The real channel structures 220R may each further include an insulating core within the channel layer 220A. The dummy channel structures 220D may each have a form similar to the form of each of the real channel structures 220R. For example, the dummy channel structures 220D may each include a dummy channel layer, a dummy memory layer, and a dummy insulating core.

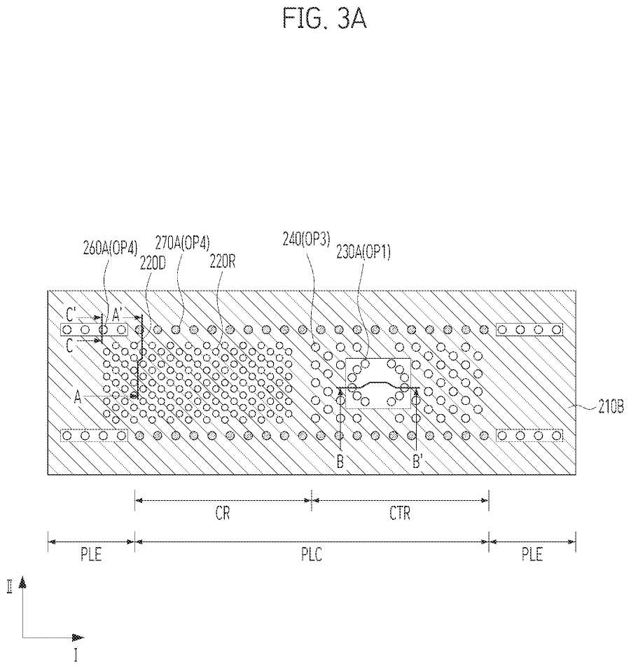

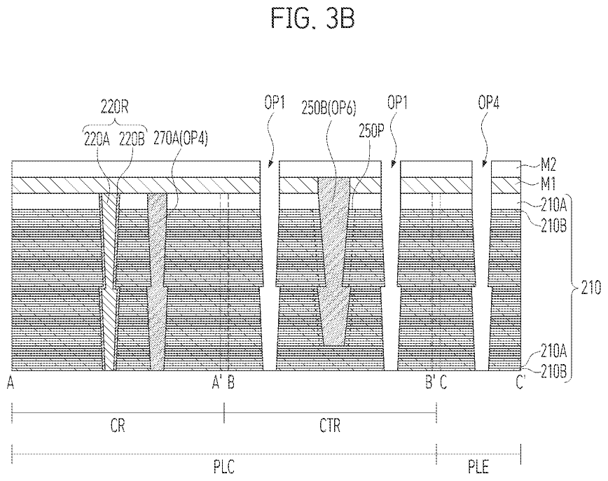

Referring to FIGS. 3A and 3B, a second sacrificial contact structure 250B extending through the stack 210 may be formed. First, a first mask pattern M1 may be formed on the stack 210. For example, the first mask pattern M1 may cover the remaining regions except the first sacrificial contact structure 250A and may expose a region corresponding to the first sacrificial contact structure 250A. Next, a sixth opening OP6 that exposes the first sacrificial contact structure 250A may be formed through the first mask pattern M1. Next, the first sacrificial contact structure 250A may be removed through the sixth opening OP6. Next, insulating spacers 250P may be formed by etching some of the second material layers 210B that have been exposed through the sixth opening OP6. The insulating spacers 250P may each include an insulating material, such as, for example, an oxide. Next, the second sacrificial contact structure 250B may be formed within the sixth opening OP6. The second sacrificial contact structure 250B may include a sacrificial material, such as, for example, polysilicon or carbon.

For reference, although not illustrated in this drawing, a plurality of sacrificial contact structures may be formed within the second sub-stack 212. The sacrificial contact structures within the second sub-stack 212 may be formed to have different heights so that the sacrificial contact structures are connected to the first material layers 210A within the second sub-stack 212, respectively, in the same manner as the first sacrificial contact structure 250A. In the process of forming the second sacrificial contact structures 250B, the first sacrificial contact structures 250A within the first sub-stack 211 and the sacrificial contact structures within the second sub-stack 212 may be removed. Accordingly, the second sacrificial contact structures 250B may be formed to have different heights so that the second sacrificial contact structures 250B are connected to the first material layers 210A within the stack 210, respectively.

Next, the first openings OP1 may be opened again. First, a second mask pattern M2 that exposes the first openings OP1 may be formed on the first mask pattern M1. Next, the first openings OP1 may be opened again by removing the first sacrificial supports 230A by using the second mask pattern M2. When the first openings OP1 are opened again, the fourth openings OP4 may be opened again. For example, the fourth openings OP4 may be the fourth openings OP4 of the plane edge region PLE. The second mask pattern M2 may expose the fourth openings OP4 of the plane edge region PLE. The fourth openings OP4 may be opened again by removing the sacrificial separation structures 260A by using the second mask pattern M2. The second mask pattern M2 may expose the first openings OP1 and the fourth openings OP4 of the plane edge region PLE and may cover the third openings OP3 and the sixth opening OP6.

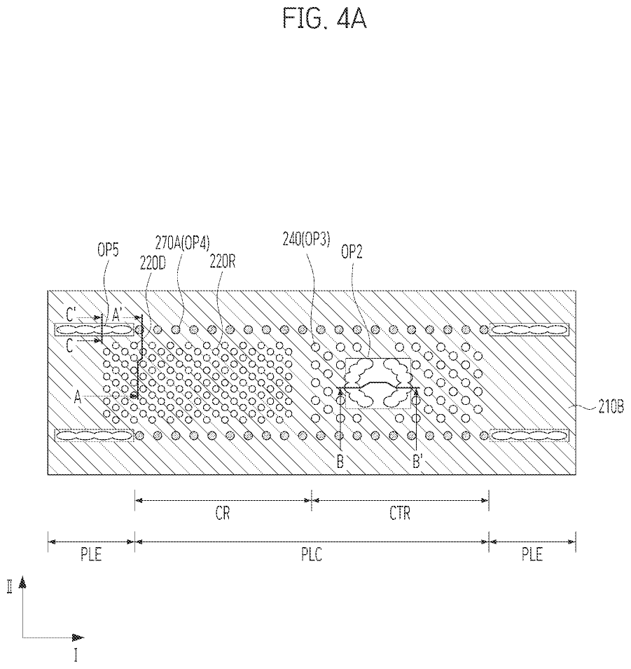

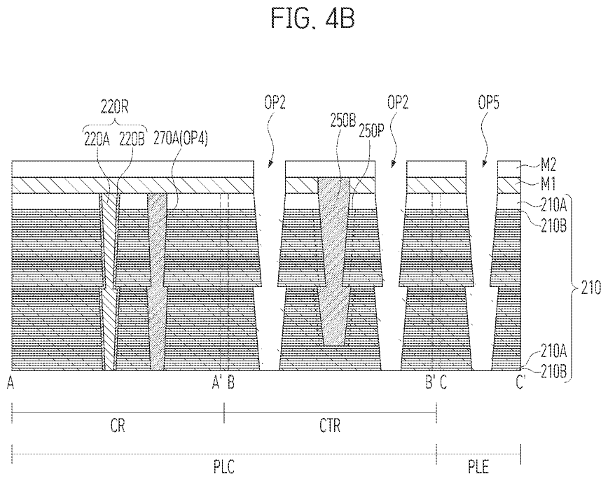

Referring to FIGS. 4A and 4B, second openings OP2 may be formed by connecting the first openings OP1. For example, the second openings OP2 may extend in an arc form and may be formed by selectively expanding the first openings OP1. For example, the arc form may mean a form in which the first openings OP1 each having a pillar form are connected. The first openings OP1 may be expanded by etching the first material layers 210A and/or the second material layers 210B that are exposed through the first openings OP1. The first group G1 and the second group G2 may each be composed of the second opening OP2 extending in the arc form. The first openings OP1 may be expanded to have an interval greater than the first interval r1 and smaller than the second interval r2. The reason for this is that if the first openings OP1 are expanded to have an interval greater than the second interval r2, a subsequent process cannot be performed because the first group G1 and the second group G2 are connected. A pair of second openings OP2 may have a form in which the pair of second openings OP2 extends in the arc form, and may have a symmetrical form in which the pair of second openings OP2 has been spaced apart from each other in the first direction I.

Fifth openings OP5 may be formed by connecting the fourth openings OP4 of the plane edge region PLE. For example, the fifth openings OP5 extending in the first direction I and that each have a line form may be formed by selectively expanding the fourth openings OP4. The fourth openings OP4 may be expanded by etching the first material layers 210A and/or the second material layers 210B that are exposed through the fourth openings OP4.

When the first openings OP1 are expanded, the fourth openings OP4 may be expanded. For example, when the first openings OP1 are expanded through the second mask pattern M2, the fourth openings OP4 may also be simultaneously expanded. Accordingly, a manufacturing process can be simplified by unifying the processes of expanding the first openings OP1 and the fourth openings OP4.

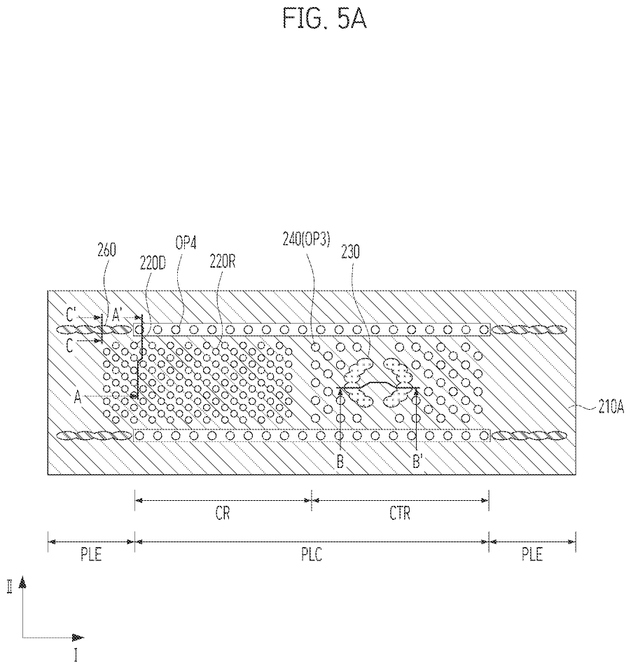

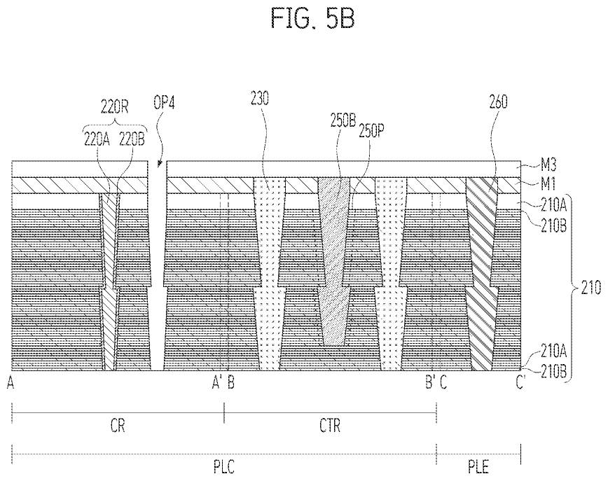

Referring to FIGS. 5A and 5B, a pair of first supports 230 that each extends in an arc form may be formed within the second openings OP2. For example, the pair of first supports 230 may include a first support and a second support positioned symmetrically against each other. Each support 230 may include concave and convex parts forming their sidewalls. In order to improve the degree of integration of semiconductor devices, forms of supports for preventing the bending of the stack 210 as the height of the stack 210 is increased are diversified. According to an embodiment of the present disclosure, the first supports 230 can support the stack 210 more robustly than supports, each one having a pillar form, because the first supports 230 are formed within the second opening OP2 extending in the arc form, respectively, by connecting the first openings OP1 each having a pillar form. Accordingly, the bending of the stack 210 can be prevented although the height of the stack 210 is increased. The first supports 230 may each include an insulating material, such as, for example, an oxide.

A separation structure 260 extending in the first direction I and that has a line form may be formed within each of the fifth openings OP5. For example, the separation structure 260 may extend in the line form and may have concave and convex parts forming the sidewalls of the separation structure 260. The separation structure 260 may include an insulating material, such as, for example, an oxide.

When the first supports 230 are formed, the separation structure 260 may be formed. After the first support 230 and the separation structure 260 are formed, the second mask pattern M2 may be removed.

Next, the fourth openings OP4 of the plane center region PLC may be opened again. First, a third mask pattern M3 may be formed on the first mask pattern M1. For example, the third mask pattern M3 may expose the fourth openings OP4 of the plane center region PLC, among the fourth openings OP4, and may cover the remaining regions. Next, the sacrificial slit structures 270A may be exposed through the third mask pattern M3. Next, the fourth openings OP4 of the plane center region PLC may be opened again by removing the sacrificial slit structures 270A.

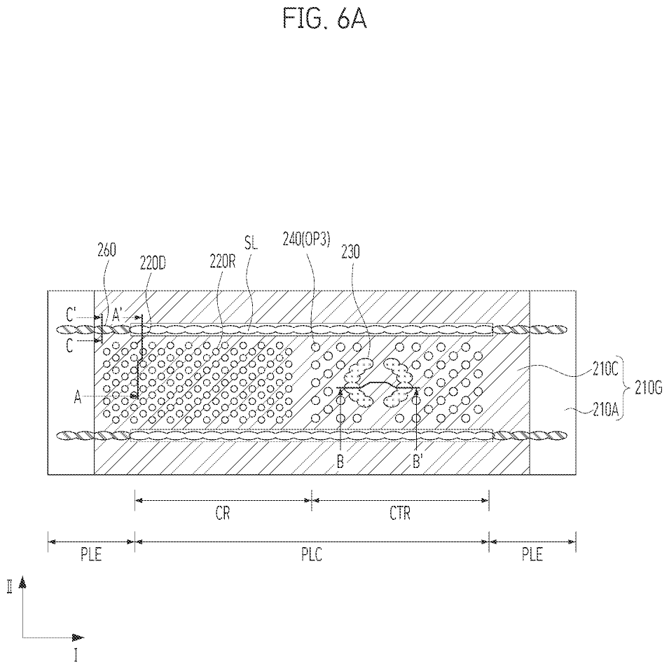

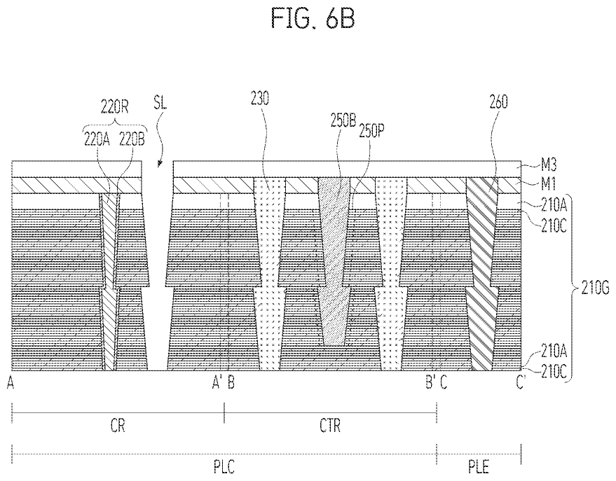

Referring to FIGS. 6A and 6B, slits SL may be formed by connecting the fourth openings OP4 of the plane center region PLC. For example, the slits SL extending in the first direction I and that have a line form may be formed by selectively expanding the fourth openings OP4 of the plane center region PLC. For example, the sidewall of the separation structure 260 may be exposed by the slit SL.

Next, the second material layers 210B may be substituted with the third material layers 210C through the slit SL. For example, the third material layers 210C may each include a conductive material, such as, for example, tungsten. Accordingly, a gate structure 210G including the first material layers 210A and the third material layers 210C that are alternately stacked may be formed. However, if each of the second material layers 210B includes a conductive material, the process of substituting the second material layers 210B with the third material layers 210C may be omitted. For example, the stack 210 may be used as the gate structure 210G. Furthermore, the stack 210 between the separation structures 260 might not be substituted with the gate structure 210G. The reason for this is that in the process of substituting the second material layers 210B with the third material layers 210C through the slit SL, the second material layers 210B that have been disposed at a relatively long distance from the slit SL and that have been formed at the end of the plane edge region PLE might not be removed.

In the process of forming the gate structure 210G, the first supports 230 and the second supports 240 can reduce the bending of the stack 210. The first supports 230 having an arc form can support the stack 210 more robustly than the first support 230 having a pillar form because the first supports 230 are formed in a form in which the first supports 230 extend in the arc form. Furthermore, in the process of removing the second material layers 210B through the slit SL of the plane center region PLC and forming the third material layers 210C, part of the second material layers 210B of the plane edge region PLE may remain in the separation structures 260 that have been previously formed in the plane edge region PLE. Accordingly, the separation structures 260 can be prevented from being mutually electrically connected through the plane edge region PLE between memory blocks.

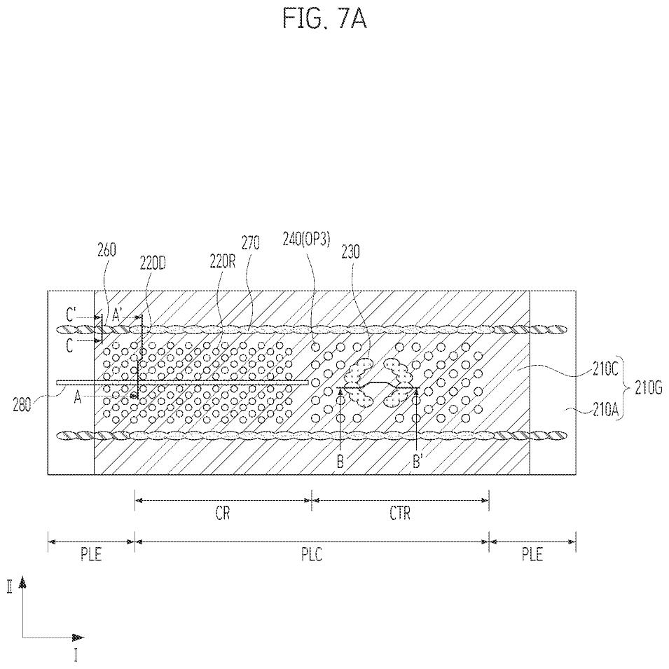

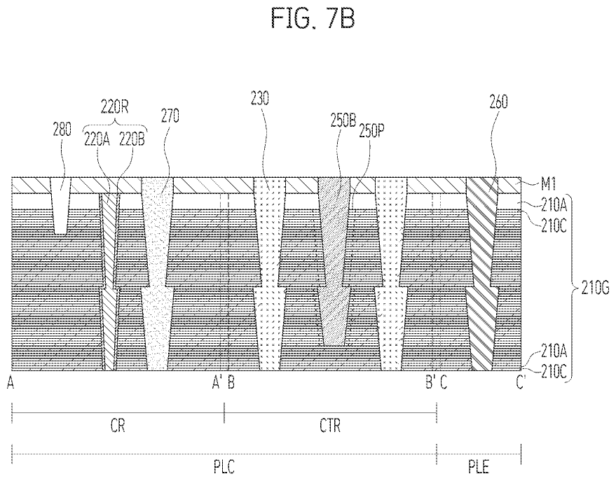

Referring to FIGS. 7A and 7B, a slit structure 270 may be formed within the slit SL. The slit structure 270 may be connected to the separation structure 260. For example, the slit structure 270 may protrude into the separation structure 260. The slit structure 270 and the separation structure 260 may be separate layers that are formed by separate processes, but an interface may be present or might not be present between the slit structure 270 and the separation structure 260. The slit structure 270 may include an insulating material, such as, for example, an oxide. Next, the third mask pattern M3 may be removed.

An insulating structure 280 may be formed within the gate structure 210G. For example, the insulating structure 280 extending into the gate structure 210G may be formed through the first mask pattern M1. The insulating structure 280 may extend in the first direction I and may be disposed between the dummy channel structures 220D or between the real channel structures 220R. For example, the insulating structure 280 may penetrate part of at least one of the dummy channel structures 220D or at least one of the real channel structures 220R. The insulating structure 280 may have a lower height than the separation structure 260 or the slit structure 270. The insulating structure 280 may have a height that penetrates a source selection line or a drain selection line. The insulating structure 280 may include an insulating material, such as, for example, an oxide.

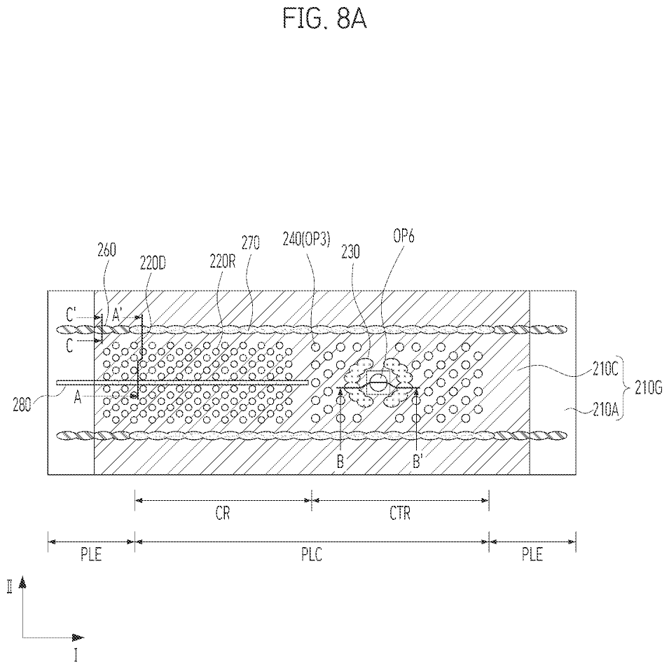

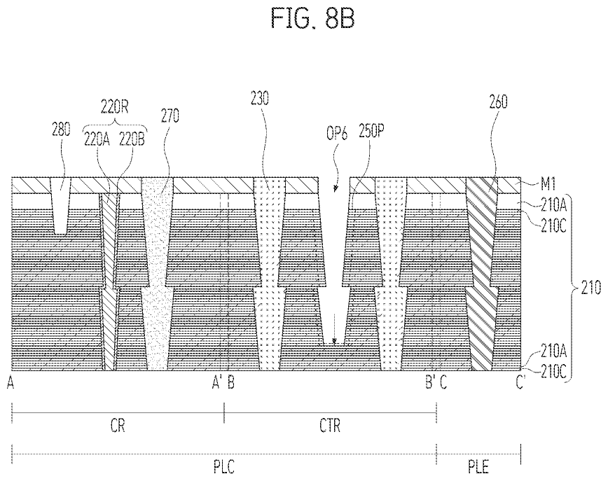

Referring to FIGS. 8A and 8B, the sixth opening OP6 may be opened again by removing the second sacrificial contact structure 250B. Next, the sixth opening OP6 may be expanded by removing the first material layer 210A that is exposed to the bottom of the sixth opening OP6. Accordingly, the third material layer 210C may be exposed.

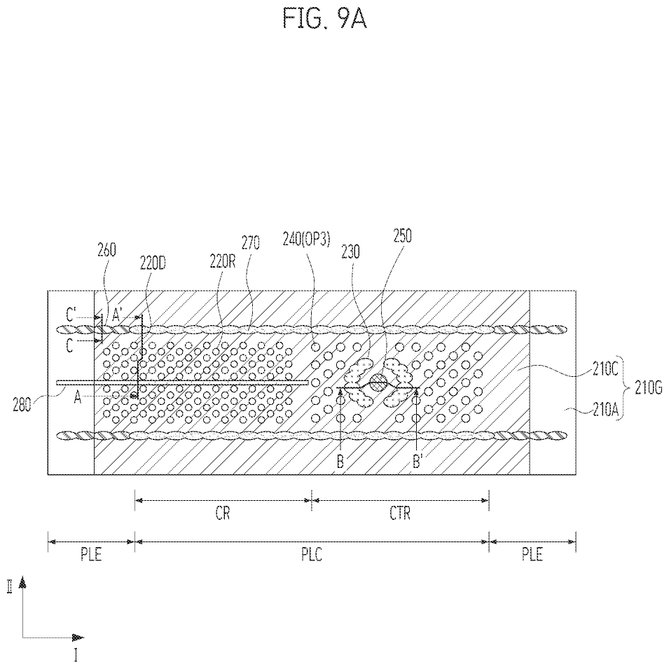

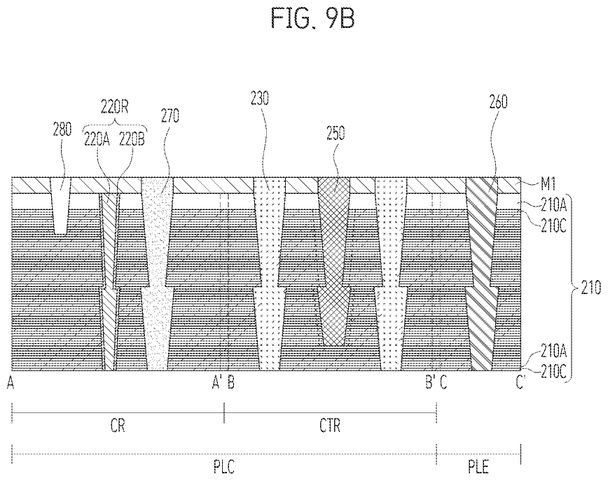

Referring to FIGS. 9A and 9B, a contact structure 250 may be formed within the sixth opening OP6. The contact structure 250 may be disposed between the pair of first supports 230 and may be connected to at least one third material layer 210C, among the third material layers 210C. The contact structure 250 may include a conductive material, such as, for example, tungsten. If the second material layer 210B includes a conductive material, the contact structure 250 may be connected to at least one second material layer 210B, among the second material layers 210B, because the process of substituting the second material layer 210B with the third material layer 210C can be omitted.

For reference, although not illustrated in FIGS. 9A and 9B, the sixth openings OP6 that expose the third material layers 210C, respectively, and that have different heights may be formed within the gate structure 210G. Accordingly, the contact structures 250 may be formed within the sixth openings OP6, respectively. For example, the contact structures 250 may have different heights, and may be connected to the third material layers 210C, respectively.

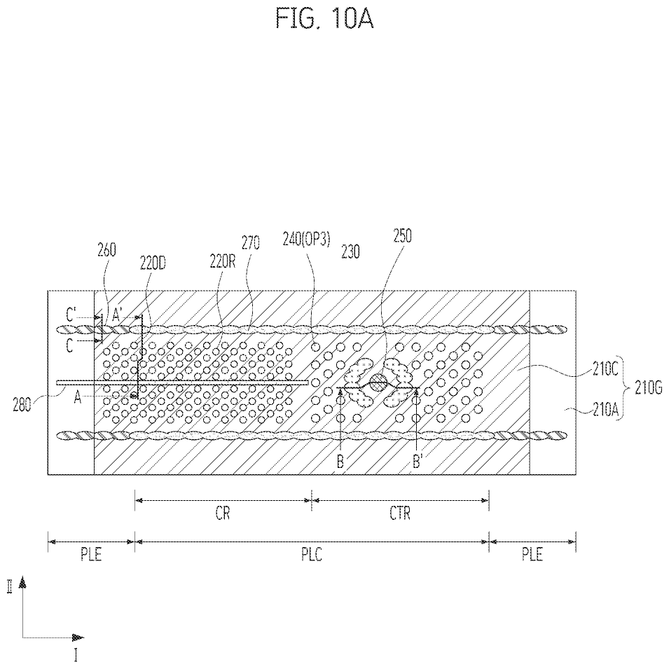

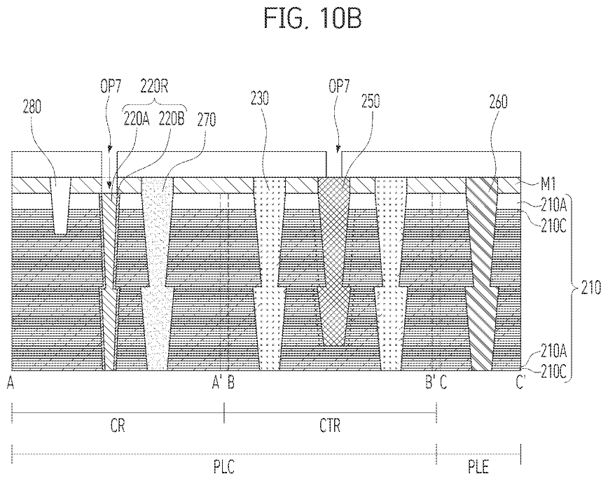

Referring to FIGS. 10A and 10B, an interlayer insulating layer IL may be formed on the first mask pattern M1. For example, the interlayer insulating layer IL may include an insulating material, such as, for example, an oxide or nitride. Seventh openings OP7 that expose the real channel structures 220R or the contact structure 250 may be formed through the interlayer insulating layer IL. First, the seventh opening OP7 that exposes the contact structure 250 may be formed. For example, the seventh openings OP7 may also be formed at locations corresponding to the real channel structures 220R. Next, the seventh openings OP7 may be expanded so that the real channel structures 220R are exposed by using the contact structure 250 as an etch barrier.

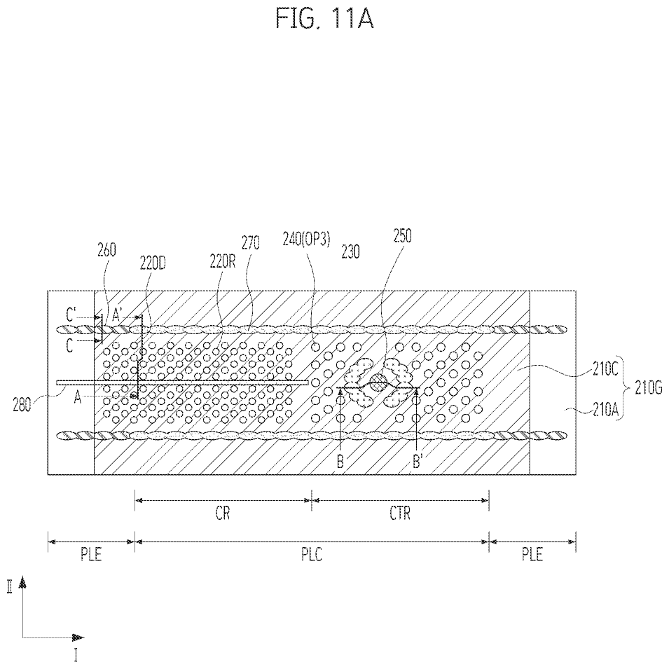

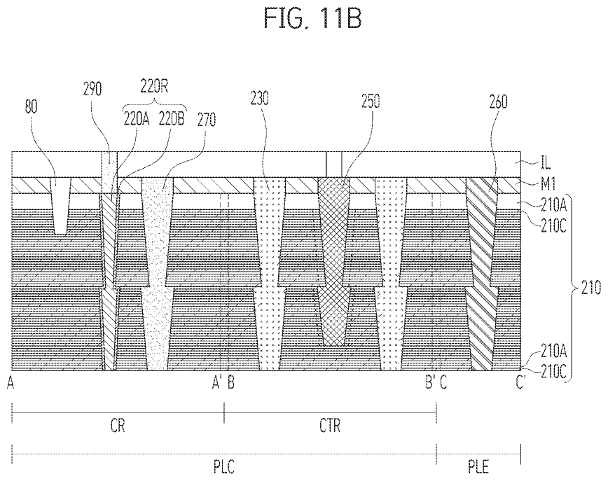

Referring to FIGS. 11A and 11B, contact vias 290 may be formed within the seventh openings OP7, respectively. Accordingly, the contact vias 290 may be electrically connected to the real channel structures 220R or may be electrically connected to the contact structure 250. The contact via 290 may mutually connect structures disposed within the gate structure 210G and structures disposed on the gate structure 210G. The contact via 290 may include a conductive material, such as, for example, tungsten.

According to the aforementioned manufacturing method, when the first openings OP1 are formed, the fourth openings OP4 of the plane edge region PLE can be formed. Furthermore, when the second openings OP2 are formed by expanding the first openings OP1, the fifth openings OP5 can be formed by expanding the fourth openings OP4 of the plane edge region PLE. Accordingly, a manufacturing process can be simplified by simplifying the processes of forming and expanding the openings OP1 and OP4.

Furthermore, the second opening OP2 extending in the arc form can be formed by connecting the first openings OP1 arranged in the arc form. The stack 210 can be supported more robustly compared to a support having a pillar form because the first support 230 extending in the arc form is formed within the second opening OP2. Accordingly, although the height of the stack 210 is increased, the stack 210 or the gate structure 210G can be prevented from being bent in a process of forming the gate structure 210G or a process of forming the contact structure 250.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the following claims. Such substitutions, modifications, and changes may be said to belong to the scope of the present disclosure. Furthermore, the embodiments may be combined to form additional embodiments.

What is claimed is:

1. A semiconductor device comprising:
a gate structure comprising insulating layers and conductive layers that are alternately stacked;
a real channel structure extending through the gate structure;
a slit structure extending in a first direction along a sidewall of the gate structure;
a contact structure extending through the gate structure and that is electrically connected to at least one conductive layer, among the conductive layers; and
a pair of first supports extending in an arc form along a sidewall of the contact structure and that comprises concave and convex parts on sidewalls of the first supports.

2. The semiconductor device of claim 1, wherein the pair of first supports has a symmetrical form.

3. The semiconductor device of claim 1, further comprising second supports extending through the gate structure, each second support having a pillar form, wherein the second supports are arranged in the first direction and a second direction intersecting the first direction.

4. The semiconductor device of claim 1, further comprising:
a separation structure disposed in a plane edge region and connected to the slit structure in the first direction; and
a dummy channel structure extending through the gate structure and disposed between a pair of separation structures that are adjacent to each other in a second direction intersecting the first direction.

5. The semiconductor device of claim 4, wherein each of the separation structures comprises concave and convex parts on sidewalls.

6. The semiconductor device of claim 1, wherein the slit structure comprises concave and convex parts on sidewalls.

7. The semiconductor device of claim 1, wherein:
the gate structure comprises a cell region and a contact region,
the real channel structure is disposed in the cell region, and
at least one of the pairs of the first supports and the contact structure is disposed in the contact region.

8. The semiconductor device of claim 7, wherein the slit structure has a line form extending from the cell region to the contact region.

9. The semiconductor device of claim 4, wherein the pairs of the first supports have a height substantially identical with a height of the separation structure.

10. The semiconductor device of claim 4, wherein the pairs of first supports comprises first supports comprising a material same or substantially same with a material of the separation structure.

11. The semiconductor device of claim 10, wherein the first supports comprise an oxide.

12. A method of manufacturing a semiconductor device, the method comprising:
forming a stack by alternately stacking first material layers and second material layers;
forming first openings extending through the stack and are spaced apart from each other and arranged in an arc form;
forming second openings extending in the arc form by connecting the first openings;
forming, within the second openings, a pair of first supports extending in the arc form and having concave and convex parts on sidewalls; and
forming a contact structure disposed between the pair of first supports and connected to at least one second material layer, among the second material layers.

13. The method of claim 12, wherein the forming the first openings comprises:
forming a first group comprising the first openings arranged at first intervals; and
forming a second group spaced apart from the first group at a second interval greater than the first interval.

14. The method of claim 13, wherein the first group and the second group have a symmetrical form.

15. The method of claim 13, wherein when the first group is formed, the second group is formed.

16. The method of claim 12, further comprising:
forming third openings extending through the stack and that are arranged in a first direction and a second direction that intersects the first direction; and
forming second supports each having a pillar form within the third openings, respectively.

17. The method of claim 16, wherein when the first openings are formed, the third openings are formed.

18. The method of claim 16, further comprising forming, on the stack, a mask pattern over the third openings exposing the first openings,
wherein the first openings are selectively expanded by using the mask pattern.

19. The method of claim 18, further comprising:
forming fourth openings extending through the stack and that are spaced apart from each other and arranged in the first direction;
forming fifth openings extending in the first direction by selectively expanding the fourth openings disposed in a plane edge region, among the fourth openings; and
forming a separation structure within the fifth openings.

20. The method of claim 19, wherein the mask pattern that exposes the first openings comprises a mask pattern that exposes the fourth openings disposed in the plane edge region.

21. The method of claim 20, wherein the first openings and the fourth openings are selectively expanded by using the mask pattern.

22. The method of claim 19, wherein when the first supports are formed, the separation structure is formed.

23. The method of claim 19, further comprising:
forming a slit extending in the first direction and exposing the separation structure by connecting remaining fourth openings, among the fourth openings;
substituting the second material layers with third material layers through the slit; and
forming a slit structure within the slit.

24. The method of claim 12, further comprising forming a real channel structure extending through the stack,
wherein the stack comprises a cell region and a contact region, the real channel structure is formed in the cell region, and at least one of the first supports and the contact structure are formed in the contact region.
